(19) United States
(12) Patent Application Publication
(10) Pub. No.: US 2025/0183065 A1
(43) Pub. Date: Jun. 5, 2025

(54) FLANGE AND APPARATUS FOR PROCESSING SUBSTRATES

(71) Applicant: ASM IP Holding B.V., Almere (NL)

(72) Inventors: Jeroen de Jonge, Almere (NL); Sumit Sachdeva, Best (NL); Lucian Jdira, Nieuw Vennep (NL); Julien Laurentius Antonius Maria Keijser, Amersfoort (NL); Theodorus G.M. Oosterlaken, Oudewater (NL)

(21) Appl. No.: 19/042,286

(22) Filed: Jan. 31, 2025

Related U.S. Application Data
(62) Division of application No. 17/323,288, filed on May 18, 2021, now Pat. No. 12,243,757.
(60) Provisional application No. 63/028,102, filed on May 21, 2020.

(51) Int. Cl. H01L 21/67; F27B 17/00; F27D 5/00; F27D 9/00; H01L 21/673

(52) U.S. Cl. CPC H01L 21/67109; F27B 17/0025; F27D 5/0037; H01L 21/67303; F27D 2009/0013

(57) ABSTRACT

The disclosure relates to a flange for a process tube in an apparatus for processing substrates, e.g., a vertical furnace. The flange may be provided with an opening for in use giving access to the process chamber of the process tube and a cooling channel for allowing a cooling fluid to flow there through and cool the flange. A material with a heat conductivity between 0.1 and 40 W/m K may be at least partially provided in between the cooling fluid and the rest of the flange.

### CROSS-REFERENCE TO RELATED APPLICATIONS

This application is a divisional of, and claims priority to, U.S. patent application Ser. No. 17/323,288 filed May 18, 2021 and titled FLANGE AND APPARATUS FOR PROCESSING SUBSTRATES; which claims priority to U.S. Provisional Patent Application Ser. No. 63/028,102 filed May 21, 2020 and titled FLANGE AND APPARATUS FOR PROCESSING SUBSTRATES; the disclosures of which is hereby incorporated by reference in their entirety.

### FIELD

The disclosure relates to a flange for a process tube in an apparatus for processing substrates. The flange may be provided with an opening for in use giving access to the interior of the process tube and a cooling channel for allowing a cooling fluid to flow and cool the flange.

More in particular the disclosure relates to an apparatus for processing substrates, comprising:
a process tube creating a process chamber and provided with an opening at a lower end;
a heater surrounding the process tube for heating the process tube;
a flange for the process tube comprising an opening aligned with the opening of the process tube and a seal to seal the process chamber, and,
a cooling channel for allowing a cooling fluid to flow there through and cool the seal.

### BACKGROUND

Semiconductor substrates can be processed in batches in vertical furnaces. An example of such processing is the deposition of layers of various materials on the substrates. For a variety of reasons, including uniformity of electrical and physical properties, high purity and uniformity is typically desired for the deposited layers. Deposition results, however, can be adversely affected by the presence of particulate matter in the furnace. In some cases, the particles can come to rest on or be incorporated into the layers, thus degrading the purity and uniformity of the deposited layers. Accordingly, to consistently achieve high quality process results, a need exists for processing methods and systems that can consistently achieve low particle levels.

The particles may be a result of the formation of reaction by-products that condense at lower temperatures on one of the flanges near the opening of the process tube. Therefore the temperature of the flanges may be kept at an increased temperature during processing to avoid condensation. When a hot wafer load is however unloaded from the reaction tube the hot load may radiate heat to the flanges which may heat the flange further up. Sealing O-rings that may be used to seal the flange against the tube or other parts of the furnace may get overheated and start leaking by this heat up. To circumvent overheating, flanges may be provided with temperature control.

### SUMMARY

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

It may be an objective to provide a flange with an improved temperature control such that overheating of the seals and/or too much condensation of the by-products may be avoided.

According to an aspect there may be provided, a flange for a process tube in an apparatus for processing substrates. The flange being provided with an opening for in use giving access to a process chamber of the process tube and a cooling channel for allowing a cooling fluid to flow there through and cool the flange. A material with a heat conductivity between 0.1 and 40 W/m K is at least partially provided in between the cooling fluid and the rest of the flange.

According to another aspect there may be provided an apparatus for processing substrates, comprising:
a process tube creating a process chamber and provided with an opening at a lower end;
a heater surrounding the process tube for heating the process tube;
a flange for the process tube comprising an opening aligned with the opening of the process tube and a seal to seal the process chamber, and,
a cooling channel for allowing a cooling fluid to flow there through and cool the seal. A material with a heat conductivity between 0.1 and 40 W/m K may be at least partially provided in between the cooling fluid and the seal.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE FIGURES

While the specification concludes with claims particularly pointing out and distinctly claiming what is regarded as embodiments of the invention, the advantages of embodiments of the disclosure may be more readily ascertained from the description of certain examples of the embodiments of the disclosure when read in conjunction with the accompanying drawings, in which:

FIG. 1 is a schematic view of the lower end of a process tube of a vertical furnace in a closed condition.

FIG. 2 is a detailed cross-sectional view of a cooling channel in a flange according to an embodiment.

FIG. 3 is a schematic cross-sectional view of a cooling channel in a flange according to an embodiment.

FIG. 4 is a schematic top view on a cooling channel according to an embodiment.

### DETAILED DESCRIPTION OF THE FIGURES

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below. The illustrations presented herein are not meant to be actual views of any particular material, structure, or device, but are merely idealized representations that are used to describe embodiments of the disclosure.

As used herein, the term “substrate” or “wafer” may refer to any underlying material or materials that may be used, or upon which, a device, a circuit, or a film may be formed. The term “semiconductor device structure” may refer to any portion of a processed, or partially processed, semiconductor structure that is, includes, or defines at least a portion of an active or passive component of a semiconductor device to be formed on or in a semiconductor substrate.

Semiconductor substrates can be processed in batches in vertical furnaces. An example of such processing is the deposition of layers of various materials on the substrates. Some of the process may be based on chlorides and ammonia for example. Chloride based chemistries using ammonia may be susceptible to the formation of particles. Without being limited by theory, it may be believed that the formation of particles may be a result of condensation of NH₄Cl on cold spots of the furnace, typically on the flanges. Therefore, the flanges may be heated to temperatures high enough to prevent condensation of NH₄Cl. Other processes may be susceptible to condensation issues and require the flanges to be heated as well. The flanges may be heated, for example, to a temperature of 100° C. or higher, more preferably 120° C. or higher, even more preferably 150° C. or higher and most preferably 180° C. or higher.

As noted above, in addition to being heated, the flanges may typically also be cooled to, e.g., prevent heat damage to O-rings which may be used to seal the flanges. While the cooling system preferably effectively prevents overheating of the substrate, it preferably does not cool the flange so greatly that the flange may be cooled below the temperatures desired for preventing condensation. In view of these conflicting requirements, preferred embodiments of the invention provide a cooling system, which may effectively and uniformly cool a flange or other furnace structure without overcooling.

The flange may be provided with a fluid cooling system in which a fluid, preferably water, is flowed through a channel. The channel may be disposed in a space of the flange and may be partially distanced from the walls of the space. Where the channel abuts the walls of the space there may be the principal conduits for thermal transfer between the flange and the channel. Adequate cooling can be facilitated by using an effective cooling medium, such as unheated water at or below room temperature. Advantageously, such a cooling system may be particularly simple and also effective. The use of limited contact between the channel and the wall have been found to be more reliable and simpler than using heated cooling media like warm or hot water or heated glycol, etc., to guard against overcooling of the flange. It also may help against overheating of the cooling medium, which can eventually result in degradation or boiling of the cooling fluid or can cause the formation of deposits in the channels through which the cooling medium circulates.

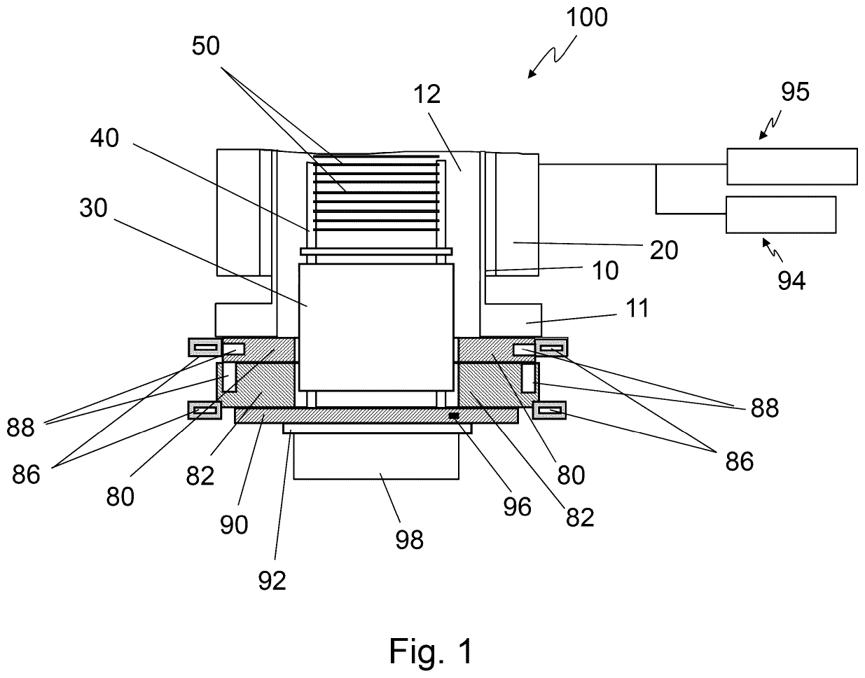

FIGS. 1, 2, 3 and 4 illustrate schematically a portion of an exemplary batch reactor. The illustrated reactor may be a vertical furnace type of reactor, which has benefits for efficient heating and loading sequences, but the skilled artisan will appreciate that the principles and advantages disclosed herein may be applied to other types of reactors.

FIG. 1 shows a cross-sectional side view of a lower section of a process tube 10 of a vertical furnace 100. The process tube 10 may be open at the bottom end and closed at the top (not shown) in a dome shape. The process tube 10 may define a process chamber 12. A heater 20 may surround the process tube 10 for heating the process tube. A pedestal 30 may support a wafer boat 40, which holds a plurality of wafers 50, preferably 50 or more wafers. The pedestal 30 may be thermally insulating, to prevent undue heating of a surrounding part of the vertical furnace 100 including a door plate 90 supporting the pedestal 30.

The process tube 10 (only the bottom end of which is shown) may have a widened base 11 which may be supported on a flange, such as an upper flange 80 or a lower flange 82. Additional flanges may be used surrounding the process tube 10 to seal it off. Flanges may also be used to support other components in the process tub such as injectors or liners.

The flanges 80, 82 may be provided with a substantially circular opening for in use giving access to the interior of the process tube 10 for example to move the substantially circular pedestal 30 with a wafer boat 40, which holds a plurality of wafers 50 into the process chamber 12. The door plate 90 seals against the lower end of the lower flange 82 when the door plate 90 is in a closed position. It will be appreciated that the door plate 90 can be formed of a single type of material, e.g., metal, or a combination of materials, e.g., metal and quartz. The door plate 90 may be vertically movable and lifts to close the opening of the process tube 10 and the flanges by sealing against the lower flange 82. The door plate 90 opens by moving downward relative to the lower flange 82. An upper surface of the door plate 90 supports the pedestal 30, which in turn supports the wafer boat 40. An elevator 98 may be provided to move, e.g., lift or lower, the door plate 90, pedestal 30 and wafer boat 40 to load or unload the wafer boat 40.

Gases, including inert and reactive precursor gases, may be provided to the process chamber 12 from gas sources 95, which may comprise a plurality of containers for holding various gases. In some embodiments, the precursor gases may include ammonia (NH₃) and/or chloride-containing gases, such as SiH₂Cl₂, TiCl₄, HfCl₄, and/or AlCl₃. The flow of precursor gases from the gas sources 95 into the process chamber 12 may be controlled by a controller 94. A gas opening (not shown) may be provided in the flanges 80, 82 to provide the gas from the gas source 95 to the process chamber 12 with for example an injector.

A gas opening in the flange may also be used to remove gases from the process chamber 12. The reactive precursor gases may create reaction by-products which may cause condensation on the cooler parts of the vertical furnace 100 such as, for example, the flanges 80, 82 and or the doorplate 90.

The door plate 90 may be a difficult to control in temperature. With each unloading of the wafer boat 40 the door plate 90 moves away from the hot furnace 100 in a downward direction and cools down significantly. After loading a newly loaded boat 40 into the furnace 100 again, the door plate 90 will be heated with heat coming from the hot parts of the furnace above the door plate 90 and from the heated flanges 80, 82. The insulation value of the pedestal 30 can be adjusted within certain limits to increase the heat reaching the door plate 90, to sufficiently heat the door plate 90 to prevent condensation.

With reference to FIG. 1, in addition to or as an alternative to adjusting the insulation value of the pedestal 30 to supply sufficient heat to the door plate 90, a door plate heater 92 may be provided. The door plate heater 92 is preferably provided below the pedestal 30.

The temperature of the door plate 90 can be monitored in various ways. For example, a temperature sensor 96 is preferably provided to actively monitor and control the door plate temperature. Temperature sensor 96 is in communication with controller 94. After a desired door plate temperature is reached, the controller 94 causes reactant gases to flow from the gas source 95 into the process chamber 12 to perform various processes, including chemical vapor deposition of films on substrates.

The upper and lower flanges 80, 82 may be provided with electrical heaters 88 to increase the temperature of the flanges, to minimize condensation on the flanges. In an exemplary design for a furnace which processes 300 mm wafer, the flanges 80, 82 may be provided with more than 20 heaters, each heater providing a maximum of about 100 Watt of heat. It will be appreciated that the number of heaters depends upon the design of the flanges, the design and power of the heaters, the heat insulation of the pedestal 30 and on the amount of insulation material provided at the outside of the tube 10 and the flanges 80, 82. For example, more heaters may be used if the heaters were less powerful, if the pedestal 30 was highly insulating and, thus, minimized heat reaching the flanges 80, 82 from the upper parts of the furnace 100, and/or if the flanges 80, 82 lost significant amounts of heat due to minimal insulation of those flanges. Conversely, fewer heaters may be used if the heaters were more powerful, if the pedestal 30 did not significantly thermally insulate the flanges 80, 82 from the upper parts of the furnace 100, and/or if the flanges 80, 82 were well insulated from heat loss.

During unloading of a processed wafer load, hot wafers 50 and hot wafer boat 40 may pass the flanges 80, 82. Without precautions, O-rings in the flanges 80, 82, which contact other surfaces to provide a vacuum tight seal, may overheat. Deterioration of the O-rings would undesirably reduce the ability to isolate the atmosphere inside the process tube 10 from the ambient environment and could potentially result in contamination or otherwise adversely influence process results. Therefore, cooling channels 86 may be provided to prevent overheating of the O-rings.

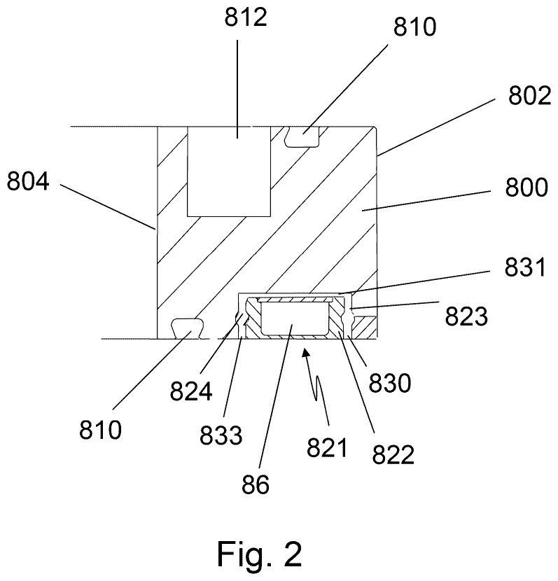

The channels 86 may be provided with a flowing fluid to remove heat from the flanges 80, 82, to cool the O-rings in contact with those flanges. A possible fluid for the channels 86 may be water. However, water boils at 100° C. and has a large cooling capacity, which may cause the flange to be cooled too much which may lead to condensation of reaction by products on the substantial circular inner surface of the flanges 80, 82 creating the opening. A design according to some preferred embodiments may avoid these and other disadvantages and may allow the use of water cooling. As shown schematically in FIG. 1, the water cooling channels 86 may be provided in less intimate contact with flanges 80, 82. The cooling channels 86 may be shown in more detail in FIGS. 2, 3 and 4.

With reference to FIG. 2, a cross section of a flange 800 is shown with an outer surface 802 and an inner surface 804. The inner surface 804 may be substantially circular. It may be appreciated that the flange 800 can be, e.g., any of the upper and lower flanges 80, 82 of FIG. 1. For example, where the flange 800 may be the lower flange 82 of FIG. 1, a heater 812, corresponding to heaters 88 (FIG. 1), may be provided. The flange may be provided with top and bottom surfaces in which recesses 810 may be formed to provide space for O-rings to allow the flange 82 to seal against neighboring structures. Such structures may be for example doorplate 90, upper flange 80 and/or tube 10 (FIG. 1).

With continued reference to FIG. 2, walls 822 of an enclosure 821 for holding coolant fluid define a cooling channel 86. The enclosure 821 may extend partially around the perimeter of the flange 800 and the cooling channel 86 may also extend partially around the perimeter of the flange 800 to facilitate even cooling of that flange. For example, in the illustrated embodiment, where the flange 800 is circular in a horizontal cross-section, the enclosure 821 may be partially in the shape of an annular ring. The enclosure 821 may be removable to, e.g., facilitate furnace maintenance.

The flange 800 may be provided with a space for at least partially or completely accommodating the cooling channel 86. For example, an enclosure 821 defining the cooling channel 86 may be accommodated in a recess 823 defining the space in the flange 800. The recess 823 may extend partially or fully around the flange 800. The enclosure 821 may extend along the recess 823 to allow even cooling of the flange 800. The recess 823 may be provided in a top, bottom or outer surface 802 of the flange 800. The recess 823 may be larger than the enclosure 821. Thus, the recess 823 e.g., the cooling channel 86 may have inner walls spaced from the outer walls of the enclosure 821, so that open space 830, 831 and 832 may be present between the enclosure 821 and the flange 800.

The space for accommodating the cooling channel 86 formed by the recess 823 may therefore be larger than the space necessary for the cooling channel 86 leaving an open space. The open space may be provided with a material with a heat conductivity between 0.1 and 40, preferably between 0.5 and 10, and even more preferably 1 and 6 W/m K. Alternatively or additionally the walls 822 of the enclosure 821 forming the cooling channel 86 may be made of a material with a similar heat conductivity between 0.1 and 40, preferably between 0.5 and 10, and even more preferably 1 and 6 W/m. By having a material with a heat conductivity between 0.1 and 40, preferably between 0.5 and 10, and even more preferably between 1 and 6 W/m at least partially in between the cooling fluid and the rest of the flange 800 a suitable coolant fluid for the cooling channels 86 may become water. Water has a large cooling capacity but by using a material with a heat conductivity between 0.1 and 40, preferably between 0.5 and 10, and even more preferably between 1 and 6 W/m the flange 800 will not be over-cooled. The risk of condensation of reaction by-products on the substantial circular inner surface of the flanges 800 may thereby be minimized. On the other hand, the risk of boiling water in the cooling channel 86 may thereby also be minimized. The material may be applied uniformly throughout the recess 821 over the perimeter of the flange 800 with the same thickness. In this way the heat conductivity around the perimeter of the flange 800 is the same to avoid cold and hot spots in the flange 800. Advantageously, preventing overcooling by this method is more reliable and simpler than using media with less cooling capacity, including heated cooling media like warm or hot water or heated glycol.

The arrangement shown in FIG. 2 allows tailoring of the thermal conductivity between flange 800 and cooling channel 86 to accommodate different processing requirements. The size of the open space 830, 831 and 832 between the enclosure 821 e.g., cooling channel 86 and the flange 800 may be varied to vary the heat transfer between the cooling channel 86 and the flange 800. For example, the size of the recess 823 can be increased or decreased, and/or the size of the cooling channel 86 can be decreased or increased, to decrease or increase, respectively, the sizes of the open space 830, 831 and 832 between the flange 800 and the ring 821, to decrease or increase the thermal conductivity.

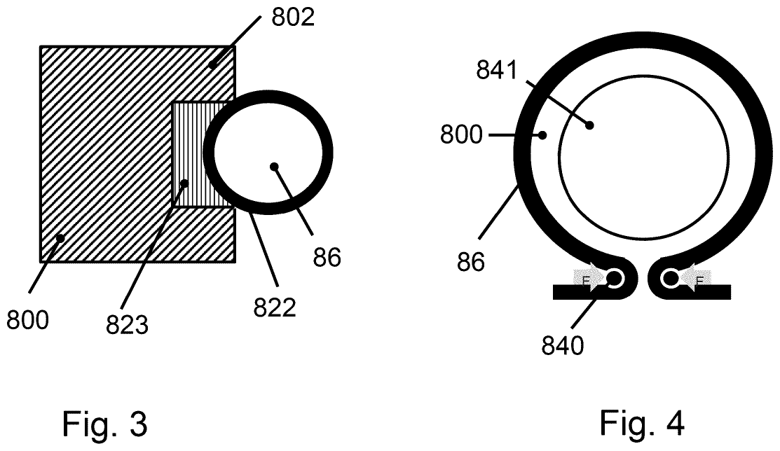

FIG. 3 is a schematic cross-sectional view of a cooling channel 86 in a flange 800 according to an embodiment. The cooling channel 86 may have a substantially circular cross section. The cooling channel 86 may be accommodated partially or completely in a recess 823 defining a space in the flange 800. A part of the space or the recess 823 may be accommodating the cooling channel 86 another part may be left open creating an open space in the recess 823. The open space may be provided with a material with the heat conductivity between 0.1 and 40, preferably between 0.5 and 10, and even more preferably 1 and 6 W/m. In this way the material is, at least partially, provided in between the cooling fluid and the rest of the flange 800.

The space or recess 823 may have a substantially rectangular cross section. The space for accommodating the cooling channel 86 may be provided in a recess 823 in the outer surface 802 of the flange 800. The opening of the recess 823 may be slightly smaller than the outer radius of the circular cross section of the cooling channel 86 so that the cooling channel 86 abuts the recess opening as shown in FIG. 3. This help in positioning the cooling channel in the recess 823. The recess opening may alternatively also be equal or bigger than the outer radius of the circular cross section of the cooling channel so that the cooling channel fits in the recess.

The wall 822 of the cooling channel 86 may comprise a metal. The cooling channel 86 may, at least partially, be surrounded by the material with the heat conductivity between 0.1 and 40 W/m K. This heat conductivity may be lower than the heat conductivity of the metal of the cooling channel 86.

The cooling channel 86 may have wall 822, which comprises the material with the heat conductivity between 0.1 and 40 W/m K. The wall 822 may comprises a multilayer e.g., a duo layer combining a metal layers with a layer of the material with the heat conductivity between 0.1 and 40 W/m K. This may be easier to manufacture or even be bought from the shelf.

The material with the heat conductivity between 0.1 and 40 W/m K may for example be selected from the group of materials comprising: lead (35 W/m K), glass (0.8 W/m K), concrete (0.8 W/m K) and polymers such as silicone (3 W/m K) and polytetrafluoroethylene (PTFE) (0.2 to 0.6 W/m K). Silicone e.g., polysiloxane is a silicon comprising polymer made up of siloxane (—R2Si—O—SiR2—, where R=organic group). Polytetrafluoroethylene (PTFE) is a polymer comprising fluorine made up of tetrafluoroethylene. The flange may be made from metal such as for example (stainless) steel or aluminum.

FIG. 4 is a schematic top view on a cooling channel according to an embodiment. The cooling channel 86 may be provided in a recess 823 provided along the perimeter of the flange 800 as for example in the flanges of FIGS. 1-3. The flange 800 may be provided with an opening 841 for in use giving access to the interior of the process tube 10.

During heating and cooling the flange 800 may expand and contract due to thermal expansion. The cooling channel may be kept very stable in temperature and may not significantly expand or contract. This may lead to a situation that the cooling channel 86 may be pressed stronger against the flange 800 when the flange is hot. This may alter the thermal conductivity and/or may decrease the quality of the material with the heat conductivity between 0.1 and 40 W/m K and/or the cooling channel 86.

A constant force actuator F, such as, for example, a spring 840 may be used to exert a constant force on the cooling channel 86. This constant force may lead to the cooling channel 86 being pressed with the same force against the flange 800 and/or the material with the heat conductivity between 0.1 and 40 W/m K over a wide temperature range of the flange 800, and over the full perimeter.

The preferred embodiments are particularly applicable to chemistries wherein a chlorine-containing reactant is used in combination with ammonia (NH₃). Examples of chlorine-containing reactants are: TiCl4, SiCl2H2, HfCl4 and AlCl3. Although the embodiments were developed in the context of a chlorine chemistry, it can be imagined that in other situations where condensable reaction by-products are generated, the principles described herein can advantageously be applied, such as in the case of organic reactant materials (e.g., alkoxymetals or alkoxy silanes).

Although illustrative embodiments of the present invention have been described above, in part with reference to the accompanying drawings, it is to be understood that the invention is not limited to these embodiments. Variations to the disclosed embodiments can be understood and effected by those skilled in the art in practicing the claimed invention, from a study of the drawings, the disclosure, and the appended claims.

Reference throughout this specification to “one embodiment” or “an embodiment” means that a particular feature, structure or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, it is noted that particular features, structures, or characteristics of one or more embodiments may be combined in any suitable manner to form new, not explicitly described embodiments.

1. An apparatus for processing substrates, comprising;
a process tube creating a process chamber and provided with an opening at a lower end;
a heater surrounding the process tube for heating the process tube;
a flange for the process tube comprising an opening giving access to the opening of the process tube and a seal to seal the process chamber, and,
a cooling channel for allowing a cooling fluid to flow there through and cool the seal, wherein a material with a heat conductivity between 0.1 and 40 W/m K is at least partially provided in between the cooling fluid and the seal.

2. The apparatus according to claim 1, wherein the apparatus comprises:
a door plate configured to support a wafer boat in the process tube, and the flange has a top and a bottom surface provided with a recess for an O-ring to function as the seal sealing the process chamber.

3. The apparatus according to claim 2, further comprising an elevator configured to move the door plate.

4. The apparatus according to claim 1, wherein the apparatus is constructed and arranged to provide water as the cooling fluid through the cooling channel.

5. The apparatus according to claim 1, further comprising a wafer boat within the process tube.

6. The apparatus according to claim 5, wherein the wafer boat holds 50 or more wafers.

7. The apparatus according to claim 5, further comprising a pedestal to support the wafer boat.

8. The apparatus according to claim 7, wherein the pedestal is thermally insulating.

9. The apparatus according to claim 7, further comprising a door plate heater below the pedestal.

10. The apparatus according to claim 1, wherein the process tube comprises a widened base, and wherein the widened base is supported by the flange.

11. The apparatus according to claim 1, further comprising a lower flange adjacent the flange.

12. The apparatus according to claim 11, wherein the lower flange comprises a flange heater.

13. The apparatus according to claim 1, wherein the flange comprises a flange heater.

14. The apparatus according to claim 1, wherein the flange comprises a gas opening to remove gases from the process chamber.

15. The apparatus according to claim 1, further comprising a controller to control a flow of gas to the process chamber.

16. The apparatus according to claim 15, wherein the controller is configured to, after a desired door plate temperature is reached, cause a reactant gas to flow from a gas source into the process chamber.

17. The apparatus according to claim 1, wherein the flange has a space that is created in a recess in the outer surface of the flange for at least partially accommodating the cooling channel, and wherein the cooling channel has a substantially circular cross section and the recess has a substantially rectangular cross section with a recess opening slightly smaller than the outer radius of the circular cross section of the cooling channel so that the cooling channel touches the recess opening.

18. The apparatus according to claim 1, wherein the cooling channel comprises a removable enclosure.

19. The apparatus according to claim 1, wherein the cooling channel is made from metal and is at least partially surrounded by a material with a heat conductivity lower than that of the metal.

20. The apparatus according to claim 1, wherein the cooling channel comprises a removable enclosure.
